(19) United States
(12) Patent Application Publication
(10) Pub. No.: US 2015/0096615 A1
(43) Pub. Date: Apr. 9, 2015

(54) SOLAR CELL AND SOLAR CELL MODULE INCLUDING THE SAME

(71) Applicant: Electronics and Telecommunications Research Institute, Daejeon (KR)

(72) Inventors: Kyu Sung LEE, Daejeon (KR); Sun Jin YUN, Daejeon (KR); JungWook LIM, Daejeon (KR)

(73) Assignee: Electronics and Telecommunications Research Institute, Daejeon (KR)

(21) Appl. No.: 14/333,967

(22) Filed: Jul. 17, 2014

(30) Foreign Application Priority Data
Oct. 4, 2013 (KR) 10-2013-0118469
Jan. 23, 2014 (KR) 10-2014-0008469

(51) Int. Cl. H01L 31/055; H01L 31/0216

(52) U.S. Cl. CPC H01L 31/055; H01L 31/02168
USPC 136/257

(57) ABSTRACT

Provided are a solar cell and a solar cell module including the same. The solar cell includes a bottom electrode layer, a light absorption layer disposed on the bottom electrode to absorb solar light of a visible light region, top electrode layer disposed on the light absorption layer, and a light conversion layer disposed on the top electrode layer.

### CROSS-REFERENCE TO RELATED APPLICATIONS

This U.S. non-provisional patent application claims priority under 35 U.S.C. §119 of Korean Patent Application Nos. 10-2013-0118469, filed on Oct. 4, 2013, and 10-2014-0008469, filed on Jan. 23, 2014, the entire contents of which are hereby incorporated by reference.

### BACKGROUND OF THE INVENTION

The present invention disclosed herein relates to a solar cell and a solar cell module including the same, and more particularly, to a solar cell including an anti-reflection layer, a light conversion layer, and a solar module including the same.

In general, the solar light spectrum may be restrictively absorbed according to kinds of material used for a light absorption layer. The silicon-based light absorption layer may have a limitation in absorption efficiency according to wavelength bands of light. For example, the silicon-based light absorption layer may absorb solar light of a visible light region. Thus, signification of the study with respect to up-conversion and down-conversion/down-shifting processes for converting solar light having a wavelength except for that of the visible light region into light having the wavelength of the visible light region is expanding. The up-conversion process may be a process for converting solar light of an infrared light region into the light of the visible light region. The down-conversion/down-shifting process may be a process for converting solar light of an ultraviolet (UV) light region into the light of the visible light region.

### SUMMARY OF THE INVENTION

The present invention provides a solar cell that is capable of maximizing light absorption efficiency and a solar cell module including the same.

Embodiments of the inventive concept provide solar cells including: a bottom electrode layer; a light absorption layer disposed on the bottom electrode to absorb solar light of a visible light region; a top electrode layer disposed on the light absorption layer; and a light conversion layer disposed on the top electrode layer, wherein the light conversion layer includes: a first anti-reflection layer refracting the solar light that is incident into the top electrode layer without reflecting the solar light; and first light conversion particles disposed between the first anti-reflection layer and the top electrode layer the first light conversion particles absorbing the solar light of an infrared or ultraviolet light region and converting the absorbed solar light into a emission light of the visible light region.

In some embodiments, the light conversion layer may be disposed between the first anti-reflection layer and the top electrode layer and further include a first refraction layer in which the first light conversion particles are inserted.

In other embodiments, the first anti-reflection layer may include aluminum oxide.

In still other embodiments, the first refraction layer may have a refractive index greater than that of the first anti-reflection layer.

In even other embodiments, the first refraction layer may include titanium oxide or vanadium oxide.

In yet other embodiments, the solar cells may further include: a second refraction layer disposed on the first anti-reflection layer, the second refraction layer having a refractive index less than that of the first anti-reflection layer; and a second anti-reflection layer disposed on the second refraction layer, the second anti-reflection layer having a refractive index less than that of the second refraction layer.

In further embodiments, the solar cell may further include second light conversion particles disposed within the second refraction layer, the second light conversion layer absorbing the solar light of the infrared or ultraviolet light region and generating the emission light.

In still further embodiments, each of the first light conversion particles may have a size greater than that of each of the second light conversion particles.

In even further embodiments, each of the first light conversion particles may have a density greater than that of the second light conversion particles.

In yet further embodiments, each of the first and second light conversion particles may include phosphors.

In much further embodiments, each of the first and second light conversion particles may include quantum dots formed of cadmium sulfide or cadmium selenide.

In still much further embodiments, the first light conversion particles may be disposed within the first anti-reflection layer.

In even much further embodiments, the first light conversion particles may have sizes gradually increasing toward the top electrode layer.

In yet much further embodiments, the first light conversion particles may have densities gradually increasing toward the top electrode layer.

In other embodiments of the inventive concept, solar cell modules include: a substrate; a solar cell disposed on the substrate; a window disposed on the solar cell; and a first light conversion layer disposed on the window, the first light conversion layer absorbing solar light of an ultraviolet light region, which is incident into the solar cell, and generating first emission layer, wherein the solar cell includes: a bottom electrode layer disposed on the substrate; a light absorption layer disposed on the bottom electrode layer to absorb the solar light and the first emission light; an top electrode layer disposed on the light absorption layer; and a second light conversion layer disposed on the top electrode, wherein the second light conversion layer includes: a first anti-reflection layer refracting the solar light and the first emission light, which are incident into the top electrode layer, without reflecting the solar light and the first emission light; and second light conversion particles disposed between the first anti-reflection layer and the top electrode layer, the second light conversion particles absorbing the solar light of an infrared light region and generating second emission light of the visible light region.

In some embodiments, the first light conversion layer may include: a first refraction layer disposed on the window to transmit the solar light; and first light conversion particles disposed within the first refraction layer.

In other embodiments, the first light conversion particles may include cadmium sulfide quantum dots.

In still other embodiments, the second light conversion particles may include phosphors.

In even other embodiments, the second light conversion layer may further include a second refraction layer disposed between the first anti-reflection layer and the top electrode layer to refract the solar light, the first emission light, and the second emission light, the second light conversion particles disposed within the second refraction layer.

In yet other embodiments, the second light conversion particles may be disposed within the first anti-reflection layer.

### BRIEF DESCRIPTION OF THE DRAWINGS

The accompanying drawings are included to provide a further understanding of the present invention, and are incorporated in and constitute a part of this specification. The drawings illustrate exemplary embodiments of the inventive concept and, together with the description, serve to explain principles of the present invention. In the drawings:

FIG. 1 is a perspective view of a solar cell module according to the present invention;

FIG. 2 is a cross-sectional view of a solar cell according to a first embodiment of the inventive concept;

FIG. 3 is a cross-sectional view of a solar cell according to a first application example of the inventive concept;

FIG. 4 is a cross-sectional view of a solar cell according to a second application example of the inventive concept;

FIG. 5 is a cross-sectional view of a solar cell according to a third application example of the inventive concept;

FIG. 6 is a cross-sectional view of a solar cell according to a second embodiment of the inventive concept;

FIG. 7 is a cross-sectional view of a solar cell according to a fourth application example of the inventive concept; and

FIG. 8 is a graph showing results obtained by comparing light absorption efficiency of the solar cells according to the first and second embodiments and the first to fourth application examples with light absorption efficiency of the solar cell according to the related art.

### DETAILED DESCRIPTION OF PREFERRED EMBODIMENTS

Exemplary embodiments of the inventive concept will be described in detail with reference to the accompanying drawings. Advantages and features of the present invention, and implementation methods thereof will be clarified through following embodiments described with reference to the accompanying drawings. The present invention may, however, be embodied in different forms and should not be construed as limited to the embodiments set forth herein. Rather, these embodiments are provided so that this disclosure will be thorough and complete, and will fully convey the scope of the present invention to those skilled in the art. Like reference numerals refer to like elements throughout.

In the following description, the technical terms are used only for explaining a specific exemplary embodiment while not limiting the present invention. The terms of a singular form may include plural forms unless specifically mentioned. The meaning of ‘comprises’ and/or ‘comprising’ specifies a component, a step, an operation and/or an element does not exclude other components, steps, operations and/or elements. Since preferred embodiments are provided below, the order of the reference numerals given in the description is not limited thereto.

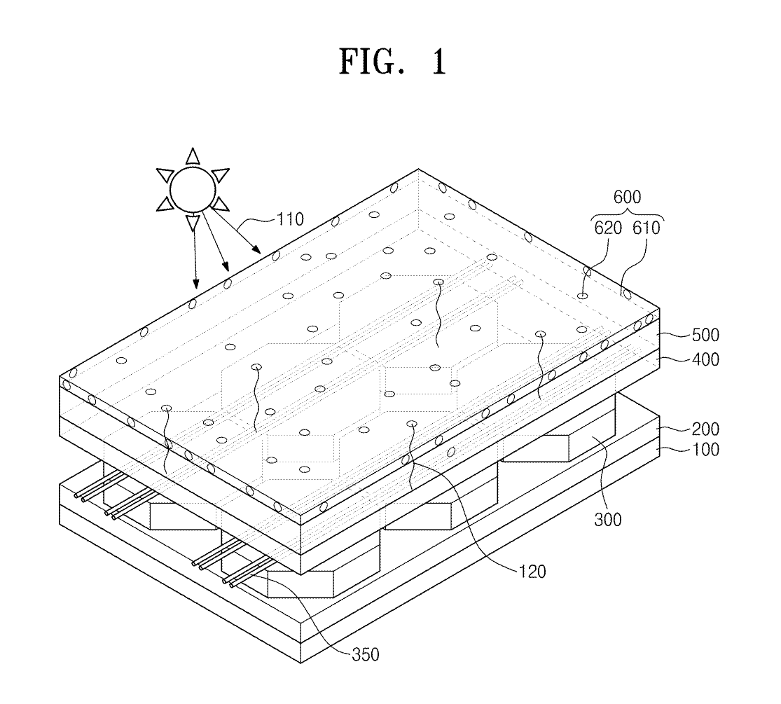

FIG. 1 is a perspective view of a solar cell module according to the present invention.

Referring to FIG. 1, a solar cell module of the present invention may include a substrate 100, a rear encapsulant 200, solar cells 300, a front encapsulant 400, a window layer 500, and a module-side light conversion layer 600.

The substrate 100 may include a reflection plate or a transparent plate.

The rear encapsulant 200 may be disposed on the substrate 100. The rear encapsulant 200 may include a transparent material. For example, the rear encapsulant may include transparent polymer or transparent plastic.

The solar cells 300 may be disposed on the rear encapsulant 200. The solar cells 300 may absorb solar light 100 to generate electric power. Each of the solar cells 300 may be connected to the substrate 100 and grids 390. The substrate 100 and the grids 390 may output the electric power to the outside.

The front encapsulant 400 may be disposed on the solar cells 300. The front encapsulant 400 may include a transparent material. The front encapsulant 400 may include transparent polymer or transparent plastic.

The window layer 500 may be disposed on the front encapsulant 400. The window layer 500 may include the front encapsulant 400. The window layer 500 may include glass or transparent plastic.

The module-side light conversion layer 600 may be disposed on the window layer 500. The module-side light conversion layer 600 may include a first refraction layer 610 and first light conversion particles 620.

The solar light 110 may be transmitted into the window layer 500 through the first refraction layer 610. The first refraction layer 610 may include metal oxide. For example, the first refraction layer 610 may include aluminum oxide (Al₂O₃), titanium oxide (TiO₂), vanadium oxide (V₂O₃), or a combination thereof.

The first light conversion particles 620 may be disposed within the first refraction layer 610. The first light conversion particles 620 may be randomly distributed within the first refraction layer 610. According to an example, the first light conversion particles 620 may absorb solar light of an ultraviolet (UV) or extreme UV light region. The first light conversion particles 620 may generate down-conversion emission light of a visible light region. The down-conversion may be defined as a process of absorbing the solar light of the UV or extreme UV light region to generate first emission light of the visible light region. For example, the first light conversion particles 620 may include quantum dots formed of cadmium sulfide (CdS) or cadmium selenide (CdSe). However, the present invention is not limited thereto. For example, the present invention may be variously modified. For example, the first light conversion particles may include the group II-VI compound semiconductors such as CdSe/ZnS, CdS/ZnS, and ZnCdSe, the group III-V compound semiconductors such as GaAs and InP, and the group IV compound semiconductors such as Si and Ge.

The solar cells 300 may absorb the solar light 110 of the visible light region and the down-conversion emission light 120 from the first light conversion particles 620 to generate the electric power. The first light conversion particles 620 may improve light absorption efficiency of the solar cells 300.

Also, the solar cells 300 may improve light absorption efficiency without reflecting the solar light 110 and the down-conversion emission light 120.

Hereinafter, the solar cells 300 according to embodiments will be described in detail.

### First Embodiment

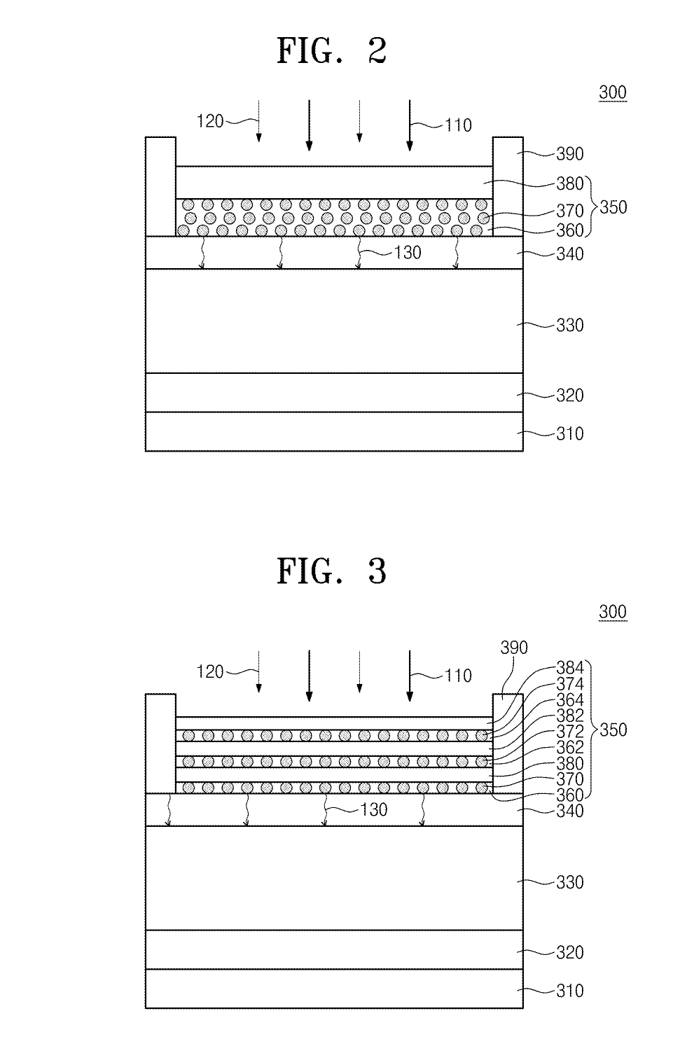

FIG. 2 is a cross-sectional view of a solar cell according to a first embodiment of the inventive concept.

Referring to FIG. 2, a solar cell according to the first embodiment of the inventive concept may include a bottom electrode layer 310, a passivation layer 320, a light absorption layer 330, a top electrode layer 340, and a device-side light conversion layer 350.

The bottom electrode layer 310 may include a transparent electrode. For example, the bottom electrode layer 310 may include indium tin oxide (ITO) or indium zinc oxide (IZO).

The passivation layer 320 may be disposed on the bottom electrode layer 310. According to an example, the passivation layer 320 may include a transparent layer. For example, the passivation layer 320 may include amorphous silicon, silicon oxide, silicon nitride, or silicon oxynitride.

The light absorption layer 330 may absorb the solar light of the visible light region and the first emission light. The light absorption layer 330 may generate electric power. For example, the light absorption layer 330 may include single crystal silicon. However, the present invention is not limited thereto. For example, the present invention may be variously modified. The light absorption layer 330 may include the group III-V and/or group II-VI compound semiconductor.

The top electrode layer 340 may be disposed on the light absorption layer 330. The top electrode layer 340 may include a transparent electrode. For example, the top electrode layer 340 may include indium tin oxide (ITO) or indium zinc oxide (IZO).

The device-side light conversion layer 350 may be disposed on the top electrode layer 340. The device-side light conversion layer 350 may include a first refraction layer 360, second light conversion particles 370, and a first anti-reflection layer 380.

The first refraction layer 360 may be disposed on the top electrode layer 340. The first refraction layer 360 may be formed using a sol-gel method or thin film deposition method. The device-side light conversion layer 350 may refract solar light and down-conversion emission light 120. Here, the solar light may have wavelengths of the visible and infrared light regions. The first refraction layer 360 may include titanium oxide (TiO₂). The titanium oxide (TiO₂) may have a refractive index of about 2.3 to about 2.5. However, the present invention is not limited thereto. For example, the present invention may be variously modified. The first refraction layer 360 may include aluminum oxide (Al₂O₃).

The second light conversion particles 370 may be disposed within the first refraction layer 360. The second light conversion particles 370 may absorb the solar light 110 of the infrared light region. The solar light 110 of the infrared light region may have a wavelength greater than that of the solar light 110 of the UV and/or visible light region. The second light conversion particles 370 may generate up-conversion emission light 130. The up-conversion may be defined as a process of absorbing the solar light 110 of the infrared light region to generate the up-conversion emission light 130 of the visible light region. For example, the second light conversion particles 370 may include phosphors formed of lanthanum-based metal particles. The light absorption layer 330 may absorb the solar light 110 of the visible light region, the down-conversion emission light 120, and the up-conversion emission light 130. However, the present invention is not limited thereto. For example, the present invention may be variously modified. The second light conversion particles 370 may include quantum dots formed of cadmium sulfide (CdS) or cadmium selenide (CdSe) or semiconductor thin film particles generating down-conversion.

A first anti-reflection layer 380 is disposed on the first refraction layer 360. The firs anti-reflection layer 380 may be formed by using a sol-gel method. The first anti-reflection layer 380 may refract the solar light 110 and the down-conversion emission light 120 without reflecting the solar light 110 and the down-conversion emission light 120. The first anti-reflection layer 380 may have a refractive index less than that of the first refraction layer 36. For example, the first anti-reflection layer 380 may include aluminum oxide (Al₂O₃). The aluminum oxide (Al₂O₃) may have a refractive index of about 1.7.

The light absorption layer 330 may absorb the solar light 110, the down-conversion emission light 120, and the up-conversion emission light 130. The solar light 110, the down-conversion emission light 120, and the up-conversion emission light 130 may have a wavelength of the visible region. Thus, the solar cell 300 according to the first embodiment of the inventive concept may improve light absorption efficiency.

FIG. 3 is a cross-sectional view of a solar cell 300 according to a first application example of the inventive concept.

Referring to FIG. 3, the solar cell 300 according to the first application example of the inventive concept may include a device-side light conversion layer 350 including a first refraction layer 360, second light conversion particles 370, a first anti-reflection layer 380, a second refraction layer 362, third light conversion particles 372, second anti-reflection layer 382, a third refraction layer 364, fourth light conversion particles 374, and a third anti-reflection layer 384.

The second refraction layer 362 may be disposed on the first anti-reflection layer 360. The second refraction layer 362 may be formed by using a sol-gel method. The second refraction layer 362 may refract solar light 110, down-conversion emission light 120, and up-conversion light 130. Here, the solar light 110 may have wavelengths of visible and infrared light regions. For example, the second insulation layer 362 may include aluminum oxide or hafnium oxide.

The third light conversion particles 372 may be disposed within the second refraction layer 362. The third light conversion particles 372 may absorb the solar light 110 of the infrared light region. The third light conversion particles 372 may generate up-conversion emission light 130 of the visible light region. The up-conversion emission light 130 may be provided into the light absorption layer 330. The third light conversion particles 372 may include phosphors.

The second anti-reflection layer 382 is disposed on the second refraction layer 362. The second anti-reflection layer 382 may be formed by using the sol-gel method. The second anti-reflection layer 382 may refract the solar light 110, the down-conversion emission light 120, and the up-conversion light 130 without reflecting the solar light 110, the down-conversion emission light 120, and the up-conversion light 130. The second anti-reflection layer 382 may include aluminum oxide (Al₂O₃).

The third refraction layer 364 may be disposed on the second anti-reflection layer 382. The third refraction layer 364 may refract the solar light 110, the down-conversion emission light 120, and the up-conversion light 130. For example, the second insulation layer 362 may include aluminum oxide or hafnium oxide.

The fourth light conversion particles 374 may be disposed within the third refraction layer 364. The fourth light conversion particles 374 may absorb the solar light 110 of the infrared light region. The fourth light conversion particles 374 may generate the up-conversion emission light 130 of the visible light region. The fourth light conversion particles 374 may include phosphors.

The third anti-reflection layer 384 is disposed on the third refraction layer 364. The third anti-reflection layer 384 may refract the solar light 110 and the down-conversion emission light 120 without reflecting the solar light 110 and the down-conversion emission light 120. The third anti-reflection layer 384 may include aluminum oxide (Al₂O₃).

In the first application example, the second refraction layer 362, the third light conversion particles 372, the second anti-reflection layer 382, the third refraction layer 364, the fourth light conversion particles 374, and the third anti-reflection layer 382 are stacked on the first anti-reflection layer 380.

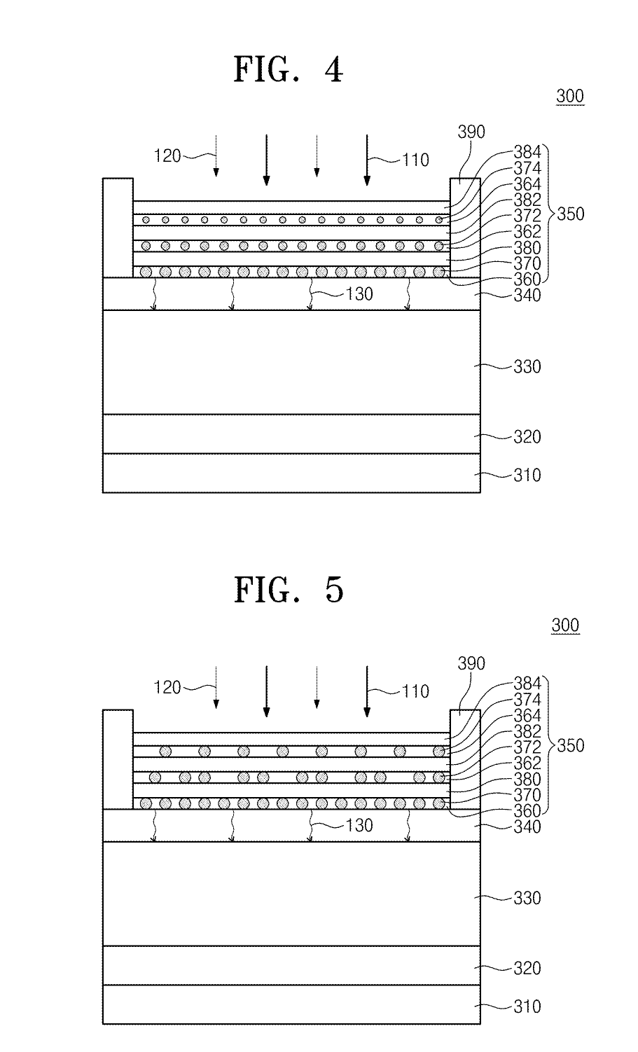

FIG. 4 is a view of a solar cell 300 according to a second application example of the inventive concept.

Referring to FIG. 4, the solar cell 300 according to the second application example of the inventive concept may include a device-side light conversion layer 350 including second light conversion particles 370, third light conversion particles 372, and fourth light conversion particles 374 which have sizes different from each other. For example, each of the third light conversion particles 372 may have a size less than that of each of the second light conversion particles 370. Each of the fourth light conversion particles 374 may have a size less than that of each of the third light conversion particles 372. The second light conversion particles 370, the third light conversion particles 372, and the fourth light conversion particles 374 may include phosphors. The phosphors may have sizes gradually decreasing in a direction that is away from the top electrode layer 340.

In the second application example, the second light conversion particles 370, the third light conversion particles 372, and the fourth light conversion particles 374 may have sizes different from each other.

FIG. 5 is a view of a solar cell 300 according to a third application example of the inventive concept.

Referring to FIG. 5, the solar cell 300 according to the third application example of the inventive concept may include a device-side light conversion layer 350 including second light conversion particles 370, third light conversion particles 372, and fourth light conversion particles 374 which have densities different from each other. For example, the third light conversion particles 372 may have a density less than that of the second light conversion particles 370. The fourth light conversion particles 374 may have a density less than that of the third light conversion particles 372. The fourth light conversion particles 374 may have densities gradually decreasing in a direction that is away from the top electrode layer 340.

In the third application example, the second light conversion particles 370, the third light conversion particles 372, and the fourth light conversion particles 374 may have densities different from each other.

### Second Embodiment

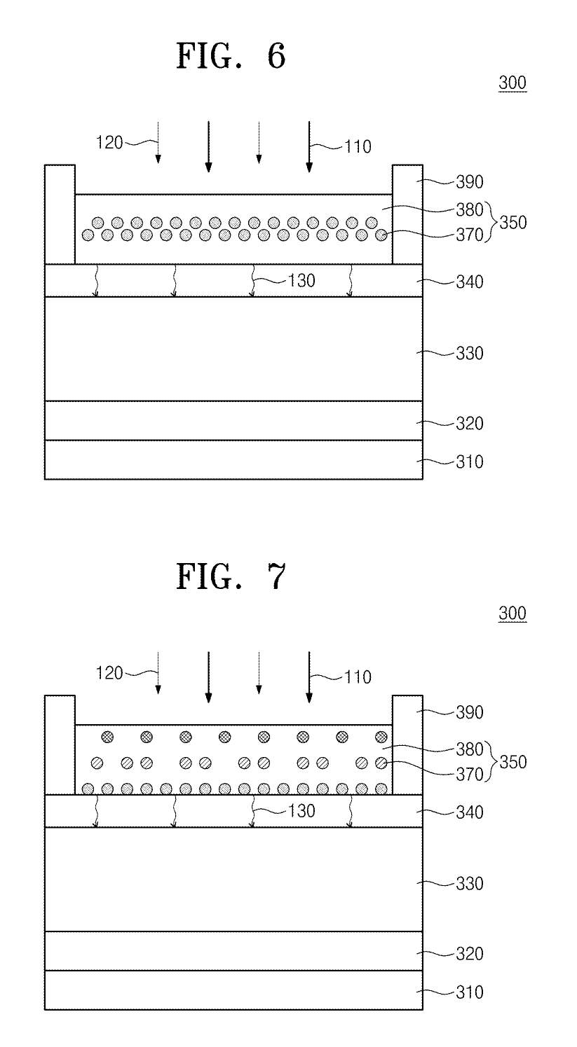

FIG. 6 is a cross-sectional view of a solar cell 300 according to a second embodiment of the inventive concept.

Referring to FIG. 6, the solar cell 300 according to the second embodiment of the inventive concept may include a device-side light conversion layer 350 including a first anti-reflection layer 380 and second light conversion particles 370 disposed within the first anti-reflection layer 380. The second light conversion particles 370 may absorb solar light 110 of an infrared light region. The second light conversion particles 370 may generate up-conversion emission light 130. For example, the second light conversion particles 370 may include phosphors formed of lanthanum-based metal particles. However, the present invention is not limited thereto. For example, the present invention may be variously modified. The second light conversion particles 370 may absorb solar light 110 of an infrared light region. The second light conversion particles 370 may generate down-conversion emission light 120. The second light conversion particles 370 may include cadmium sulfide quantum dots.

In the second embodiment, the second light conversion particles 370 according to the first embodiment may be disposed within the first anti-reflection layer 380.

FIG. 7 is a view of a solar cell 300 according to a fourth application example of the inventive concept.

Referring to FIG. 7, the solar cell 300 according to the fourth application example of the inventive concept may include a device-side light conversion layer 350 including second light conversion particles 370 having densities different from each other in a depth direction of the a first anti-reflection layer 380. For example, the second light may have densities gradually decreasing in a direction that is away from a light absorption layer 330 and a top electrode layer 340.

In the fourth embodiment, the second light conversion particles 370 according to the second embodiment may have densities that are different in the depth direction of the first anti-reflection layer 380.

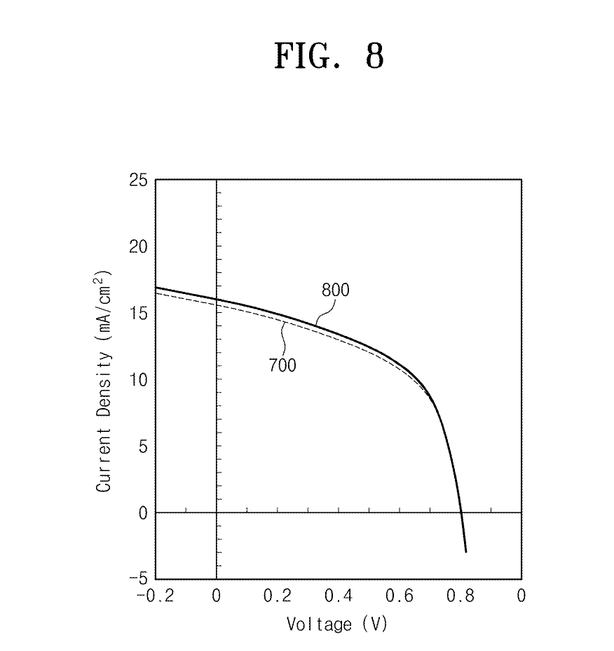

FIG. 8 is a graph showing results obtained by comparing light absorption efficiency of the solar cells according to the first and second embodiments and the first to fourth application examples with light absorption efficiency of the solar cell according to the related art.

Referring to FIGS. 1 to 8, light absorption efficiency 800 of the solar cell 300 according to the first and second embodiments and the first to fourth application example of the inventive concept may have a short current density greater than that of light absorption efficiency 700 of the solar cell according to the related art. Here, a horizontal axis may represent a voltage, and a vertical axis may represent a short current density.

The short current density may increase by the up-conversion emission light 130 or down-conversion emission light 120 of the second to fourth light conversion particles 370, 372, and 374. Also, the short current density may increase by the transmission of the solar light 110, the up-conversion emission light 130, and down-conversion emission light 120 through the first to third anti-reflection layers 380, 382, and 384.

As described above, the solar cell module of the present invention may include the solar cell including the module-side light conversion layer that generates the down conversion emission light and the device-side light conversion layer that generates the up-conversion emission light. The light absorption layer of the solar cell may absorb the solar light of the visible light region, the down-conversion emission light, and the up-conversion emission light to generate power. Thus, the solar cell module of the present invention may improve the light absorption efficiency when compared to that of the solar cell module according to the related art.

The above-disclosed subject matter is to be considered illustrative, and not restrictive, and the appended claims are intended to cover all such modifications, enhancements, and other embodiments, which fall within the true spirit and scope of the present invention. Thus, to the maximum extent allowed by law, the scope of the present invention is to be determined by the broadest permissible interpretation of the following claims and their equivalents, and shall not be restricted or limited by the foregoing detailed description.

What is claimed is:

1. A solar cell comprising:
a bottom electrode layer;
a light absorption layer disposed on the bottom electrode to absorb solar light of a visible light region;
a top electrode layer disposed on the light absorption layer; and
a light conversion layer disposed on the top electrode layer,
wherein the light conversion layer comprises:
a first anti-reflection layer refracting the solar light that is incident into the top electrode layer without reflecting the solar light; and
first light conversion particles disposed between the first anti-reflection layer and the top electrode layer, the first light conversion particles absorbing the solar light of an infrared or ultraviolet light region and converting the absorbed solar light into a emission light of the visible light region.

2. The solar cell of claim 1, wherein the light conversion layer is disposed between the first anti-reflection layer and the top electrode layer and further comprises a first refraction layer in which the first light conversion particles are inserted.

3. The solar cell of claim 2, wherein the first anti-reflection layer comprises aluminum oxide.

4. The solar cell of claim 2, wherein the first refraction layer has a refractive index greater than that of the first anti-reflection layer.

5. The solar cell of claim 2, wherein the first refraction layer comprises titanium oxide or vanadium oxide.

6. The solar cell of claim 2, further comprising:
a second refraction layer disposed on the first anti-reflection layer, the second refraction layer having a refractive index less than that of the first anti-reflection layer; and
a second anti-reflection layer disposed on the second refraction layer, the second anti-reflection layer having a refractive index less than that of the second refraction layer.

7. The solar cell of claim 6, further comprising second light conversion particles disposed within the second refraction layer, the second light conversion particles absorbing the solar light of the infrared or ultraviolet light region and generating the emission light.

8. The solar cell of claim 7, wherein each of the first light conversion particles has a size greater than that of each of the second light conversion particles.

9. The solar cell of claim 6, wherein each of the first light conversion particles has a density greater than that of the second light conversion particles.

10. The solar cell of claim 9, wherein each of the first and second light conversion particles comprises phosphors.

11. The solar cell of claim 9, wherein each of the first and second light conversion particles comprises quantum dots formed of cadmium sulfide or cadmium selenide.

12. The solar cell of claim 1, wherein the first light conversion particles are disposed within the first anti-reflection layer.

13. The solar cell of claim 12, wherein the first light conversion particles have sizes gradually increasing toward the top electrode layer.

14. The solar cell of claim 12, wherein the first light conversion particles have densities gradually increasing toward the top electrode layer.

15. A solar cell module comprising:
a substrate;
a solar cell disposed on the substrate;
a window disposed on the solar cell; and
a first light conversion layer disposed on the window, the first light conversion layer absorbing solar light of an ultraviolet light region which is incident into the solar cell and generating a first emission layer,
wherein the solar cell comprises:
a bottom electrode layer disposed on the substrate;
a light absorption layer disposed on the bottom electrode layer to absorb the solar light and the first emission light;
an top electrode layer disposed on the light absorption layer; and
a second light conversion layer disposed on the top electrode,
wherein the second light conversion layer comprises:
a first anti-reflection layer refracting the solar light and the first emission light, which are incident into the top electrode layer, without reflecting the solar light and the first emission light; and
second light conversion particles disposed between the first anti-reflection layer and the top electrode layer, the second light conversion particles absorbing the solar light of an infrared light region which is refracted from the first anti-reflection layer and generating second emission light of the visible light region.

16. The solar cell module of claim 15, wherein the first light conversion layer comprises:
a first refraction layer disposed on the window to refract the solar light; and
first light conversion particles disposed within the first refraction layer.

17. The solar cell module of claim 16, wherein the first light conversion particles comprise cadmium sulfide quantum dots.

18. The solar cell module of claim 15, wherein the second light conversion particles comprises phosphors.

19. The solar cell module of claim 15, wherein the second light conversion layer further comprises a second refraction layer disposed between the first anti-reflection layer and the top electrode layer to refract the solar light, the first emission light, and the second emission light, the second light conversion particles disposed within the second refraction layer.

20. The solar cell module of claim 15, wherein the second light conversion particles are disposed within the first anti-reflection layer.
